(19) United States
(12) Patent Application Publication
(10) Pub. No.: US 2004/0104468 A1
(43) Pub. Date: Jun. 3, 2004

(54) Semiconductor integrated circuit device and semiconductor integrated circuit chip thereof

(76) Inventors: Osamu Suzuki, Chiyoda (JP); Shigeo Ohashi, Tsuchiura (JP); Atsuo Nishihara, Kashiwa (JP); Hideaki Mori, Chiyoda (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/722,597

(22) Filed: Nov. 28, 2003

(30) Foreign Application Priority Data
Nov. 28, 2002 (JP) 2002-346160

(51) Int. Cl. H01L 23/34

(52) U.S. Cl. 257/722

(57) ABSTRACT

In a semiconductor integrated circuit device and a semiconductor integrated circuit chip, being provided for achieving small-sizing and light-weight of the entire cooling structure thereof, without lowering the permissible temperature for an integrated circuit package, a circuit forming layer 2, on which are formed a large number of circuits, is formed on one side surface of a plate-like semiconductor chip 101, and on the other side surface opposing to that forming the circuits thereon, a heat transfer layer 15 is connected with in one body. This heat transfer layer 15 is made of a material similar to that of the semiconductor chip, and within an inside thereof are formed passage ducts 3 to build up a closed flow passage. Within this closed flow passage is enclosed an operating fluid 4, such as, a water or the like, and is provided a resistor film 5 for building up a driving means of the operating fluid, in contact with the operating fluid. Vibration is given to the operating fluid, through evaporation (or bumping) due to heating by means of the resistor film 5, in a pulse-like manner, thereby transferring/diffusing a local increase of temperature, which is generated within the circuit-forming layer 2.

### BACKGROUND OF THE INVENTION

The present invention relates to a semiconductor integrated circuit device, being used in, such as, electronic equipment and appliances, widely, including a computer, etc., for example, and in particular, it relates to a semiconductor integrated circuit device and a semiconductor integrated circuit chip for it, being able to averaging or flattening temperature distribution within an inside of an element, through transfer (or diffusion) of heat generation within the integrated circuit of such the device accompanying with the operation thereof, thereby suppressing an increase of local temperature within the semiconductor chip of the integrated circuit device.

Conventionally, to be a device for diffusing (or transferring) the heat from a heat generating body, such as, a semiconductor or the like, which is mounted on the electronic equipment, a heat diffusing panel or plate is already known in the following Patent Document 1, for example, wherein a loop-like groove is formed on a contacting surface of each of an upper plate and a lower plate of high heat-conductive material, and both of those plates are connected while laying one on the top of another, so that the said loop-like grooves are opposing to each other, thereby building up a heat pipe within an inside thereof.

Also, in general, as a device for transferring heat from the heat generating body, it is also already known that the heat can be transferred by the fact of driving a fluid enclosed within an inside thereof, for example. In the device disclosed in the following Patent Document 2, for example, for the purpose of transferring the heat from a printed circuit board, on which a plural number of semiconductor devices or elements (i.e., the heat generating bodies) are mounted, with provision of an electrical heating means, which is formed in a part of the liquid flow passage formed and is built up with a capillary, the liquid within an inside of the capillary is heated up, in a pulse-like manner, thereby boiling it abruptly (i.e., generating bumping), thereby driving the liquid mentioned above, due to a sudden increase of pressure accompanying evaporation when generating the bumping.

However, the principle of transferring the heat with using such vibration of the liquid is described, in more detail, such as, in the following Non-Patent Document 1.

Also, in the following Non-Patent Document 2, in particular, in FIG. 10 thereof, there is disclosed the structure for diffusing the heat generated from the semiconductor chip having a large electric power consumption therein, by using a vessel or container building up therein a device for transferring the heart with utilizing the vibration of the heat pipe and/or the liquid.

[Patent Document 1]

Japanese Patent Laying-Open No. 2002-130964 (2002)

[Patent Document 2]

Japanese Patent Laying-Open No. Hei 7-286788 (1995)

[Non-Patent Document 1]

“Enhancement of Heat Transfer by Sinusoidal Oscillation of Fluid (Transient Behavior of a Dream Pipe)” (pp 228-235), by Mamoru OZAWA and 5 others, Vol. 56, No. 530 (1990-10), a collection of papers of Japan Machinery Institute (B-Edition)

[Non-Patent Document 2]

Z. J. Zuo, L. R. Hoover and A. L. Phillips, “An integrated thermal architecture for thermal management of high power electronics”, pp 317-336, Suresh V. Garimella, Thermal Challenges in Next Generation Electronic System (PROCESSING OF INTERNATIONAL CONFERENCE THERMES 2002), FANTA FE, N. Mex., USA, 13-16 Jan. 2002

By the way, in recent years, for the highly integrated semiconductor chips, being used for calculation processing, such as, in the computer, etc., for example, demands are made strongly, not only upon improvements in small-sizing of the chip-die size thereof and also in the speed of calculation processing much more, but also on reduction of electric power density per a chip accompanying with a demand on lower electric power consumption. For satisfying both of them, an improvement is made upon a technology of mounting a logical element and a memory element within the same chip (commonly named “System On Chip”), for example.

In such the semiconductor chip, since the memory element portions, each being smaller in the electric power density comparing to that of the logical element, are mounted on the same semiconductor chip with the logical elements, mixing up together with, therefore the electric power density per a chip is smaller comparing to that of the conventional semiconductor chip. However, seeing the semiconductor chip as a whole, a large difference is locally generated of the electric power consumption within the chip. Further, in a portion of the logical element(s), there is also produced a distribution of the electric power density, and as a result thereof, there is also generated a large difference in the electric power density within the chip.

Since the difference of the electric power density appears to be the difference of the heat generation density, as it is, in the semiconductor chip, a large temperature distribution is generated, when operating such the chip mounting the logical elements and the memory elements within the same chip, in more details, such as, a local increase of temperature (so called, a “hot spot”) within the logical element portion(s). And, if such the hot spot comes up to an upper limit of junction temperature of a transistor, it causes thermal runaway of the semiconductor element; therefore it is necessary to provide any means or measure for dissolving such the hot spot. Also, the generation of such the hot spot results in a great reason of reducing an operation permissible temperature (i.e., the maximum temperature permissible for the package, so as to guarantee a normal operation of the circuits of the semiconductor chip mounted within that package) of the integrated circuit package mounted on the said semiconductor chip. For this reason, an entire of the cooling structure comes to be large in the sized thereof, and therefore it is impossible to apply it into a small-size computer and/or a small-size electronic appliance, in particular, being necessary to be portable, such as, being called by a “desk top” type or a “note-size” type, and also to apply it into a computer, in which the integrated circuit packages are mounted in a plural number thereof with high density, such as, being called by a “lack mount server” and/or a “blade server”, etc.

On the contrary to this, for example, with such the heat transfer or diffusing mechanism shown in the Patent Document 1 and/or the Patent Document 2 mentioned above, such the structure is adopted therein, that the semiconductor elements (i.e., chips), being the heat generating body, are attached on the said heat diffusing plate through a high heat conductive grease, a high heat conductive adhesive, or a high heat conductive rubber, etc. For this reason, in case when the hot spot is generated within said heat-generating parts, this hot spot is diffused into the heat diffusing plate through the grease, the adhesive or the rubber, which is thermally connected to that heat generating parts, directly. By the way, such the grease, the adhesive or the rubber has the thermal conductivity of an order of 10 W/(m.K), at the highest, even in the case of the largest one, but this is remarkably small comparing to the thermal conductivity of metal or semiconductor; such as, aluminum or silicon (in an order of 100 W/(m.K), for example). For this reason, with such the structure, in which the semiconductor chips, being the heat generating parts, are attached onto the heat diffusing plate through the grease, the adhesive or the rubber, relating to the conventional art, there still remains a problem that a large difference of temperature occurs within the semiconductor chip due to the hot spot.

### BRIEF SUMMARY OF THE INVENTION

Then, according to the present invention, being accomplished by taking such the problems of the conventional arts mentioned above into the consideration, and in more details thereof, an object thereof is to provided a semiconductor integrated circuit device and a semiconductor integrated circuit chip for it, wherein the hot spot can be reduced, which is generated within the semiconductor chip due to the small-sizing of the chip and/or the difference in the electric power density, so as to suppress or flatten the difference in the heat distribution generated within the semiconductor chip, but without lowering the permissible temperature of the integrated circuit package mounting the semiconductor chips thereon, and as a result of this, enabling the small-sizing and light-weight of the cooling structure as a whole, with ease.

Namely, according to the present invention, for accomplishing the object mentioned above, there is provided a semiconductor integrated circuit chip, being made of a plate-like semiconductor chip, comprising: a circuit forming layer, being formed on one side surface of the plate-like semiconductor chip, in which a plural number of circuits are formed; and a heat transfer layer, being connected with the plate-like semiconductor chip in one body, on other side surface opposing to that where said circuit forming layer is formed, wherein said heat transfer layer is made of a material similar to that of said semiconductor chip, and comprises, in an inside thereof: a closed flow passage; an operating fluid hermetically enclosed within said closed flow passage; and driving means of said operating fluid the followings.

Further, according to the present invention, in the semiconductor integrated circuit chip as described in the above, both said plate-like semiconductor chip and said heat transfer layer are made of a material of silicon, or said driving means of the operating fluid is made of means for giving vibration to said operating fluid hermetically enclosed within said closed flow passage, or said vibration giving means is made up with an resistor layer. Or, said resistor layer is disposed in a region where heat generation density is lower than an averaged heat generation density of said integrated circuit chip as a whole.

Also, according to the present invention, in the semiconductor integrated circuit chip as described in the above, said operating fluid is water, or said plate-like semiconductor chip is of such a chip, wherein logic elements and memory elements are formed separately within the one side surface thereof, on which the circuits are formed.

Also, according to the present invention, in the semiconductor integrated circuit chip as described in the above, possibly, the closed flow passages, being formed in said heat transfer layer, are be formed in a plural number thereof, along with one side of said semiconductor chip, and each of the closed flow passages formed in the plural number thereof has the means for driving the operating fluid enclosed within an inside thereof, independently. and further comprising a plural number of temperature detecting means are provided within said semiconductor chip, wherein said plural number of driving means provided independently are controlled depending upon temperature detection outputs from said temperature detecting means. Or alternately, it is also possible that the semiconductor integrated circuit chip as described in the above further comprises other plural number of closed flow passages, being formed along with other side of said semiconductor chip, crossing over the plural number of said closed flow passages formed, and further, each of said closed flow passages formed in the plural number thereof has means for driving the operating fluid enclosed within an inside thereof, independently, and moreover, further comprising a plural number of temperature detecting means are provided within said semiconductor chip, wherein said plural number of driving means provided independently are controlled depending upon temperature detection outputs from said temperature detecting means.

And, also, according to the present invention, for accomplishing the object mentioned above, there is provided a semiconductor integrated circuit chip, comprising: a plate-like semiconductor chip; a circuit forming layer, being formed on one side surface of said plate-like semiconductor chip, on which a plural number of circuits are formed; and a heat transfer layer, being formed on other side surface opposing to the side surface on which said circuit forming layer is formed, for suppressing a local increase of temperature caused due to heat generation of the circuit within said circuit forming layer of said semiconductor chip, being connected therewith in one body.

In addition to the above, according to the present invention, there is further provided a semiconductor integrated circuit device, comprising: a semiconductor integrated circuit chip, in a part of which are formed circuits in a plural number thereof; a mounting board, in a part of which are formed wiring patterns, for mounting said integrated circuit chip thereon; a case for receiving said mounting board, on which said integrated circuit board is mounted, in an inside thereof; and a plural number of terminals, being planted outside from said case or said mounting board, and being electrically connected to the circuits formed on said semiconductor integrated circuit chip, wherein said semiconductor integrated circuit chip is such the semiconductor integrated circuit chip as described in the above.

And, according to the present invention, the semiconductor integrated circuit device as described in the above, further comprises a heat sink, being attached on a part of an outer surface of said case, or the electric power to be supplied to said driving means, which is formed in said heat transfer layer of said semiconductor integrated circuit chip, is a part of the electric power to be supplied to said semiconductor integrated circuit chip through said terminals of said semiconductor integrated circuit device.

### BRIEF DESCRIPTION OF THE SEVERAL VIEWS OF THE DRAWING

Those and other objects, features and advantages of the present invention will become more readily apparent from the following detailed description when taken in conjunction with the accompanying drawings wherein:

FIG. 1 is an enlarged cross-section view of a part of a semiconductor integrated circuit chip, according to one embodiment of the present invention, in particular for showing the details of a driving means thereof;

FIG. 2 is a view for explaining the condition of mounting the semiconductor integrated circuit device onto an appliance, which comprises the semiconductor integrated circuit chip therein, according to the one embodiment of the present invention;

FIG. 3 is a cross-section view for showing the internal structure of the semiconductor integrated circuit device, in which the semiconductor integrated circuit chips are installed, according to the embodiment of the present invention;

FIG. 4 is a perspective view for showing an outlook and the internal structure of the semiconductor integrated circuit chip, according to the embodiment of the present invention;

FIGS. 5(A) and 5(B) are a side view and an upper view of the semiconductor integrated circuit chip, according to the embodiment of the present invention, in particular, being seen from directions of arrows A and B shown in FIG. 4 mentioned above;

FIG. 6 is a view for showing other example of a passage duct formed on a flow passage (heat transfer) substrate in the semiconductor integrated circuit chip, according to the present invention; and

FIG. 7 is also a view for showing further other example of the passage duct formed on a flow passage (heat transfer) substrate in the semiconductor integrated circuit chip, according to the present invention.

### DETAILED DESCRIPTION OF THE INVENTION

Hereinafter, embodiments according to the present invention will be fully explained by referring to the attached drawings.

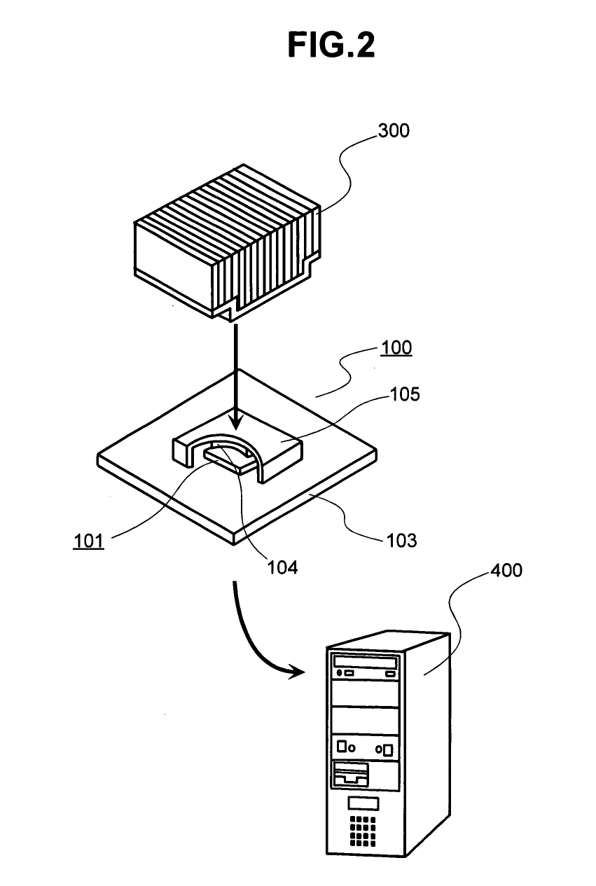

In FIG. 2 attached herewith is shown an outlook of the semiconductor integrated circuit device, according to the present invention (including also an exploded view of a part thereof). Namely, as is apparent from the figure, the semiconductor integrated circuit device 100 is made up with, such as, a ceramic of high heat conductivity, for example, wherein a package case 105, forming an about cubic external shape thereof, and a printed circuit board (a mounting board) 103 are piled up on each other, thereby defining a closed space therebetween, and within an inside thereof is mounted a semiconductor chip 101, being a circuit element made from a rectangular silicon plate, for example. Also, this semiconductor ship 101 is mounted on the printed circuit board (the mounting board) 103 and connected electrically therewith. And, through the printed circuit board 103, the circuits (for example, a CPU and/or a memory, etc.) formed within the semiconductor chip 101 are electrically connected to a plural number of external terminals 201, which are provided for electrical connection thereof to an outside, but not shown in the figure herein.

Also, as is shown in the figure, the semiconductor integrated circuit device 100 mentioned above, according to the present invention, is attached with a heat sink 300 for heat radiation on an upper surface thereof, for example, under the condition of being such the package case, and further it is mounted at a predetermined position within a cabinet (or a housing) 400 of a server, etc. Or, alternately, without being attached with such the heat sink as was mentioned above, it may be installed as it is within the electronic appliance, including the personal computer of the portable type, for example.

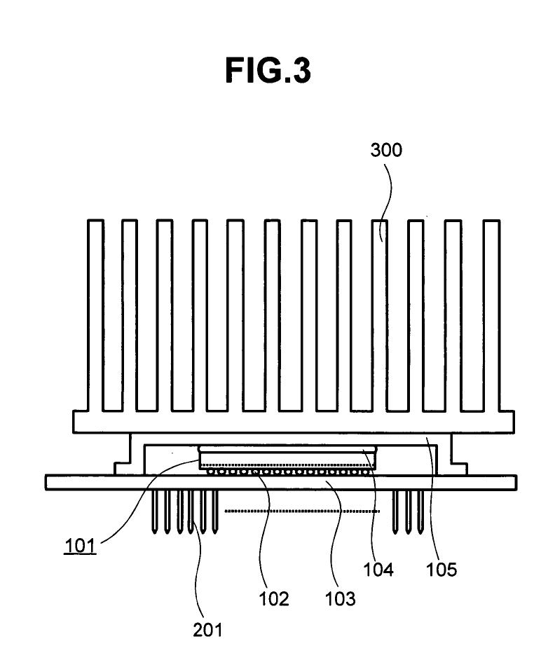

Also, the cross-section view in FIG. 3 shows the condition where the semiconductor chip 101 mentioned above is mounted on the printed circuit board 103, on the lower surface of which are planted a plural number of pins (i.e., external terminals) 201, in the semiconductor integrated circuit device 100 according to the present invention shown in FIG. 2. However, in the figure, the same reference numerals given to those shown in FIG. 2 mentioned above indicate the similar constituent elements thereof, and a reference numeral 104 in the figure is a high heat-conductive grease, a high heat-conductive adhesive, or a high heat-conductive rubber, which is inserted between the semiconductor chip 100 and the package case 105.

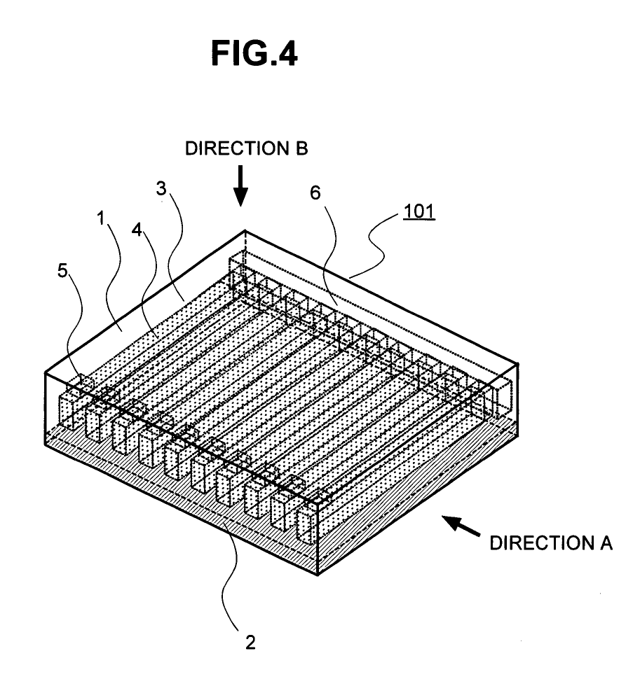

Next, FIG. 4 attached herewith shows the detailed structure of an integrated circuit board by broken lines, being the semiconductor chip (i.e., a chip-die) 101, which is mounted on the semiconductor integrated circuit device 100, according to the present invention mentioned above. Namely, in the figure, the lower side surface of the integrated circuit board 1, being the semiconductor chip 101 mentioned above, is a layer, on which a large number of circuits are formed for building up a logic element (i.e., a CPU) and/or a memory element (i.e., a memory), separating from the regions thereof, respectively, within the same chip, by applying therein the “System On Chip” technology mentioned above, for example, through the known manufacturing method of the semiconductor device; thus, being so-called an electronic circuit (or electronic circuit forming) layer 2.

On the other hand, upon an upper side surface of the integrated circuit board 1, being the semiconductor chip 101 mentioned above (i.e., the opposite surface to the electronic circuit layer 2 on the chip-die), there is formed a closed flow passage through a plural number of passage ducts 3, being integrated in one body together with the said chip (i.e., the chip-die), and an operating fluid 4 is hermetically enclosed within an inside thereof. Also, in the vicinity of one end portion of the each passage duct 3 is formed a resistor film 5 for building up a driving means of the operating fluid, while at the other end portion of the each passage duct 3 is formed a buffer 6, to be a space for communicating with each other.

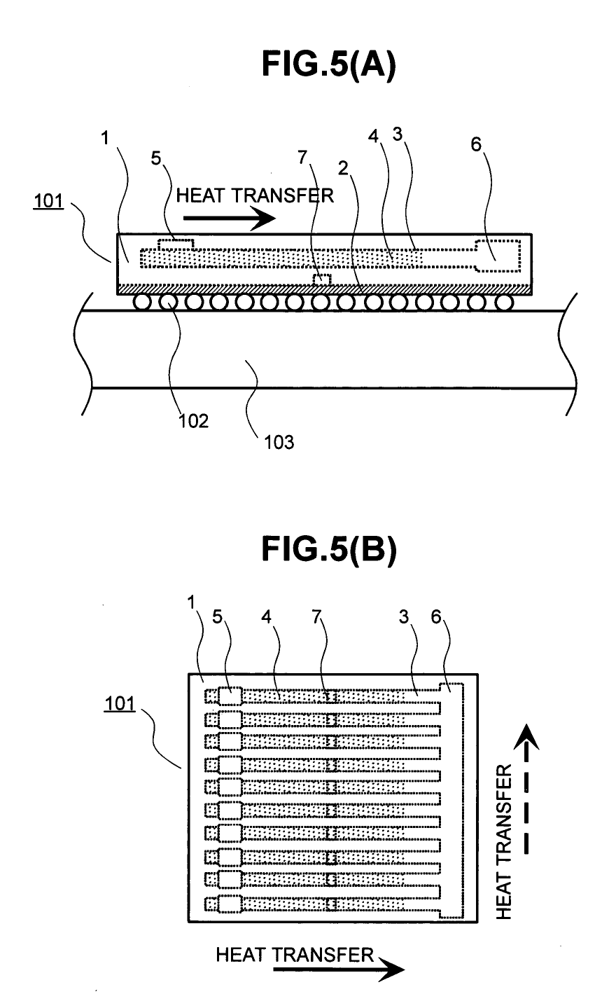

FIG. 5(A) shows the condition of the integrated circuit board 1, being the semiconductor chip 101, seen from the direction of an arrow A shown in FIG. 4 mentioned above. However, in this figure, a reference numeral 102 indicates a solder ball inserted between the electronic circuit layer 2 of the integrated circuit board 1 and the mounted board 103. Also, FIG. 5(B) shows the condition of the integrated circuit board 1, being the semiconductor chip 101, but seen from the direction of an arrow B shown in FIG. 4 mentioned above.

As is apparent from those figures, on the integrated circuit board 1 of being the semiconductor chip 101, the passage ducts and the buffer portions 6 are formed in a plural number thereof, in a comb-like shape, on the side surface opposing to the electronic circuit layer 2, along with one side of the board (i.e., a horizontal side of the semiconductor chip, in the example shown in FIG. 5(B) mentioned above), and within an inside thereof is hermetically enclosed a fluid (i.e., the operating fluid 4) having a large latent heat, such as, a water or the like, for example. Also, at an end portion or on a surface in the vicinity of those passage ducts 3, opposing to the side, on which the buffer portions 6 mentioned above are formed, there are formed the resistor films for building up the driving means of the operating fluid, at width being equal to or a little bit larger than that of the passage duct, respectively. Namely, each of the resistor films 5 is in contact with the operating fluid 4, which is hermetically enclosed within the inside of the passage duct 3 (see FIG. 5(A)). Further, with the driving means of the operating fluid mentioned above, it is preferable to be positioned in a region where the heat generating density is smaller than an averaged heat generating density of the chip as a whole, for the purpose of decreasing an ill influences receiving from heat generation of the integrated circuit device of being the semiconductor chip 101. In the present embodiment, it is formed in a region, being close to an end of the integrated circuit board 1. Alternately, it may be provided corresponding to a portion where the memory is formed, in which the heat generation is relatively small.

Also, in those FIGS. 5(A) and 5(B), a reference numeral 7 is temperature sensors for detecting the hot spot generated in the integrated circuit board 1 of being the semiconductor chip 101, and in more details thereof, each being formed to be a resistor layer formed on a lower layer of the electronic circuit layer 2. Namely, it is possible to detect the position where the hot spot is generated (in more details, at which position in the vertical direction of the integrated circuit board shown in FIG. 5(B)), by measuring the change of the resistance value of the temperature sensors 7. In the present embodiment, there is disclosed an example, where those temperature sensors 7 are located at about a center of the board 1 mentioned above, while forming them alighting to the positions where the plural number of the passage ducts 3 are formed, and directing in the orthogonal direction thereto, on one line. However, according to the present invention, it should not be restricted only to that mentioned above, however it is also possible to provide the plural number of those passage ducts 3, for example, along a plane of the integrated circuit board 1 mentioned above (i.e., forming them dispersing on the plane), appropriately.

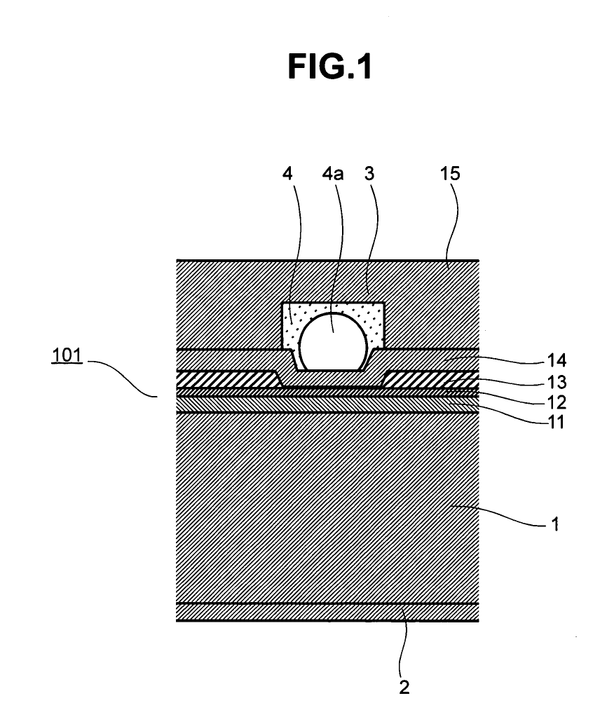

Next, FIG. 1 attached herewith is a partial enlarged cross-section view for showing the cross-section of an end portion, expansively, on which the resistor films 5 are formed for building up the driving means of the operating fluid, in the passage ducts 3 formed in the integrated circuit board I of being the semiconductor chip 101. However, in this figure, being different from the structure shown in FIGS. 5(A) and 5(B) mentioned above, there is shown an example where the resistor films 5 for building up the driving means of the operating fluid are formed on the lower side surface of the passage ducts 3 mentioned above, in the figure.

As is apparent from the figure, the integrated circuit board 1 of being the semiconductor chip 101 comprises the electronic circuit (forming) layer 2, on the lower side surface of which the circuits are formed in the large number thereof, for building up the logic element (i.e., the CPU) and the memory element (i.e., the memory) within the same chip. On the other hand, upon the upper side surface of the integrated circuit board 1 (i.e., the side opposing to the surface, on which the electronic circuit layer 2 is formed) is laminated a resistor layer 12 (such as, a layer made of polysilicon, tantalum compound (TaN), etc., for example), for forming the resistor films 5, which builds up the driving means of the operating fluid, through an insulating layer 11 (such as, a layer of SiO₂, for example).

Further, upon the upper surface are formed metal layers 13 on both sides of this resistor layer 12, so as to form wiring for supplying the resistor layer 12 with electric power, and further upon the upper surface thereof is formed a protection layer 14. And, further upon the upper surface thereof, a flow passage (or heat diffusing) layer (or substrate) 15 is connected with the integrated circuit board 1, integrated in one body, which is made from a silicon plate, being same to the integrated circuit board 1 mentioned above in the material thereof. Further, on the lower surface of the silicon plate for building up the flow passage (or heat diffusing) substrate 15, there are formed the passage ducts 3 and the buffer 6 mentioned above in the plural number thereof, in advance, via a machining technology, such as, a dry etching, etc., for example, and this flow passage substrate 15 is connected with the integrated circuit board 1 in one body.

Charging of the operating fluid is carried out, by charging a liquid, such as, a water, etc., as the operating fluid 4, into an inside of the passage ducts 3 in the plural number thereof and/or the buffer 6 mentioned above, for example, when connecting the flow passage substrate 15 onto the integrated circuit board 1 in one body. Or, alternately, though not shown in the figure herein, with provision of ports for communicating between the surfaces of the passage ducts 3 and the semiconductor chip 101, the operating fluid 4 may be charged into therefrom. Upon the charging of the operating fluid 4, the charging pressure may be changed, or a gaseous portion (i.e., an air) of non-condensable gas is mixed with when charging, depending upon the characteristics of that operating fluid 4.

Also, the material for forming the flow passage substrate 15 mentioned above should not be restricted only to the silicon, but also may be a material having the thermal expansion coefficient being similar to that of the silicon. Also, the protection layer 14 mentioned above is provided for the purpose of protecting the said resistor layer 12 from contacting with the operating fluid 4, such as of the water, etc., directly, however, it may be unnecessary depending upon selection of the materials of those resistor layer and the operating fluid.

As to the size of the semiconductor chip (i.e., the chip-die) that is mounted on the semiconductor circuit device 100, according to the present invention mentioned above, it may be assumed to be ten (10) mm to several tens mm, on the contrary to this, the cross-section of the passage duct may have a cross-section aria of ten (10) μm square to a hundred (100) μm square.

Also, though not shown in the figure herein, there is provide a means for supplying the electric power to the resistor layers 12 through the wiring made up with the wiring of those metal layers 13 mentioned above, but in an intermittent or a pulse-like manner. The pulse frequency, in this instance, though depending upon the kind of the operating fluid 4 and the size of the passage ducts 3, is about from several tens Hz to several hundreds Hz. As such the pulse electric power supply means, it may be formed on the electronic circuit layer 2 of the integrated circuit board 1, or it may be built up with the logic element, such as the CPU, formed within the forming surface of the electronic-circuit layer 2. Further, though not shown in the figure, it is also possible to utilize a portion of the electric power from a power source for supplying the driving power to the semiconductor integrated circuit device 100 according to the present invention (in more details thereof, a portion of the electric power supplied to the integrated circuit board 1 though the external terminals mentioned above), and such the structure is advantageous from a viewpoint of simplification on circuitry thereon.

Following to the above, explanation will be given in more details about the transferring (diffusing) function of the heat generation in the integrated circuit board 1, the detailed structure of which was explained in the above, by referring to FIG. 1 mentioned above, and FIGS. 5(A) and 5(B).

First, when the electric power is supplied, in the pulse-like manner, from the pulse electric power supply means mentioned above, the resistor layer 12 shown in FIG. 1 mentioned above generates heat, and then the operating fluid 4 (for example, it is the water, in the present example) within the passage duct 3 is heated abruptly (i.e., the pulse-like manner), and thereby being evaporated (i.e., generating the bumping) to generate bubbles of vapor 4a thereof within the operating fluid 4. Thereafter, when stopping the electric power supply of the pulse-like manner, the heat generation is also stopped by means of the resistor layer 12, and the generated operating fluid vapor 4a mentioned above disappears.

Further, the protection layer 14 is necessary herein, also for the purpose of protecting the resistor layer 12 from being damaged through the cavitations function, which is generated when the vapor 4a disappears. In this manner, supplying the pulse-like electric power to the resistor layers 12, intermittently, brings the operating fluid 4 enclosed inside to repeat generation and expiration of the bubbles due to the vapor 4a of the operating fluid at the end portion within the inside of the passage ducts 3. And then, when the operating fluid 4 is boiled suddenly (i.e., generating the bumping), vibration is generated due to expansion of the bubbles and following an abrupt increase of pressure accompanying with the evaporation thereof. This vibration generated drives the operating fluid 4. Namely, accompanying the vibration of the operating fluid 4 within the passage ducts 3, the heat generated in the electronic circuit layer 2 of the integrated circuit board 1 (in particular, the local increase of temperature, such as, the hot spot) can be transferred (or diffused) (see the arrows shown in FIGS. 5(A) and 5(B)), thereby averaging or flattening the temperature distribution within the integrated circuit board 1 and also suppressing the generation of the local increase of temperature.

Also, in the integrated circuit board 1 mentioned above, the passage ducts 3 are provided in the plural number thereof and in parallel to one another, on the upper side surface of the board, and further each of the passage ducts 3 is constructed, so that it can be driven and/or operated, individually or independently. Then, the pulse-like electric power supply means mentioned above detects the position of the local increase of temperature by using temperature detection signals from the temperature sensors 7, which are disposed within the board, thereby enabling to control the driving electric power to be supplied to the passage ducts 3, selectively. Namely, the pulse-like electric power is supplied (or drives), intermittently, only to the resistor layer(s) 12 of the passage duct(s) 3 corresponding to the portion(s) where the local increase of temperature, such as, the hot spot is generated in the electric circuit layer 2 of the integrated circuit board. With this, it is possible to obtain the heat transfer (or diffusion), not as a whole of the board, but only the portion where it is necessary; therefore, it is possible to achieve the heat transferring (or diffusion) function in the integrated circuit board 1, with much high efficiency.

However, in the embodiment mentioned above, the explanation was given only on the example where the passage ducts 3 are formed in the plural number thereof, only one direction (i.e., in the vertical direction in FIG. 5(B) mentioned above) but in parallel to one another, on the upper side surface of the integrated circuit board 1. But, the present invention should not be restricted only to that, and it may be also possible to form a layer of the plural number of passage ducts 3, which are formed in the horizontal direction in FIG. 5(B) mentioned above and in parallel to one another, further onto any one of the upper and lower layers thereof, in addition to the passage ducts of the plural number being formed in the vertical direction and in parallel to one another. Namely, with such the structure, in particular, when disposing the temperature sensors 7, dispersedly, within the plane surface of the board, it is possible to select the passage ducts 3 to be driven and/or controlled, in a sense of a plane (i.e., not only in the vertical direction, but also in the horizontal direction), with using the temperature detection signals from those temperature sensors 7, thereby achieving the heat transferring (diffusion) function of much higher efficiency.

Also, with the embodiment mentioned above, though the description was made only on the structure for selecting the passage ducts 3 to be driven with using the detection signals of the temperature sensors 7, however it is also possible to select and/or control the passage duct(s) 3 to be driven, but without provision of such the temperature sensors 7 within the integrated circuit board 1 as was mentioned above, for example, by calculating (or predicting) the heat generating portion upon basis of the control signals to the CPU (i.e., being the portion of large heat generation) which is formed within the electronic circuit layer 2 of the integrated circuit board 1. With such the structure, since no such the temperature sensor 7 is necessary, therefore it is possible to achieve the heat transfer (or diffusion) function with high efficiency, but with a relatively simple structure thereof, therefore it may be advantageous from an economical viewpoint.

According to the embodiment mentioned above, on one surface of the integrated circuit board 1, being the semiconductor chip 101 building up the semiconductor integrated circuit device 100, the electronic circuit layer 2 is formed, on which are formed the circuit elements accompanying the local increase of temperature, such as, the hot spot, representatively, while on the side opposing to that where the electronic circuit layer 2 is formed, there are formed the layer 15 for achieving the function of transferring (or diffusing) the heat generated within the electronic circuit layer 2 (such as, the flow passage layer (or substrate), in which the passage ducts are formed in the plural number thereof, for example), as well as, the resistor layer 12 to be the heating/driving means, in one body, made of the material being same to that of the integrated circuit board (such as, the silicon, in the present example, for example). For this reason, the heat generated within the integrated circuit board 1 of being the semiconductor chip 101 can be transferred (or diffused) with high efficiency, within an inside of the board, and therefore it is possible to suppress or eliminate the local increase of temperature, greatly, such as, the hot spot, representatively, which is caused due to the difference in the electric power density, even in the semiconductor chip applying the “System On Chip” mentioned above therein.

Furthermore, accompanying the description in the above, with the integrated circuit package, in which such the semiconductor chip is mounted, there is no necessity to set a permissible temperature thereof to be a low value when setting it, by taking the local increase of temperature into the consideration, and therefore it can be used under the condition of relatively high permissible temperature. Namely, when installing it into an appliance, the integrated circuit package can be used under the condition of relatively high permissible temperature, with ease; for example, by only attaching such the heat sink as was mentioned in the above thereto, but without accompanying with an improvement and/or high efficiency on the cooling performance for the integrated circuit package, nor large-sizing or scaling of the cooling structure thereof. Also, it is of course possible to be applied, in particular, into a small-sized computer and/or small-sized electronics, being necessary to be portable, such as, those being called by the “desk top” and/or the “note size”, for example, and also, into the computers being called by the “lack mount server” and/or the “blade server”, installing the integrated circuit packages in a plural number thereof with high density therein.

Also, as was mentioned in the above, the flow passage layer (or the substrate) 16, in which the passage ducts 3 are formed in the plural number thereof, is made of the material (such as, the silicon, in the present example, for example), being same to that of the integrated circuit board 1, or of the material being close to that in the thermal expansion coefficient thereof, integrated in one body, it is superior in the strength against the stress due to the heat generated repetitively within the integrate circuit board 1, and therefore, it is possible to protect the integrate circuit board, with certainty, from an accident of leakage of the water enclosed within the passage ducts 3, which is a fatal to the electronic circuitry, and in particular, caused by the breakage of connection portion due to such the stress thereon. Namely, it is possible to provide the semiconductor integrated circuit device equipped with the heat transfer (or diffusion) function, being superior in safety.

Furthermore, with the integrated circuit board 1 of being the semiconductor chip 101 according to the present embodiment mentioned above, in particular, the insulating film 11, the resistor layer 12, the metal films 13 for use of wiring, and the protection layer 14 are formed, piling up one another, on the side surface opposing to that on which the electronic circuit layer 2 of the board is formed, and then the flow passage layer (or the substrate) 15 is attached thereto, in which the plural passage ducts 3 are formed, in the structure thereof; i.e., it can be manufactured and achieved with ease, by applying the ordinary manufacturing technologies of the integrated circuit board, therefore it is advantageous from the economical viewpoint thereof.

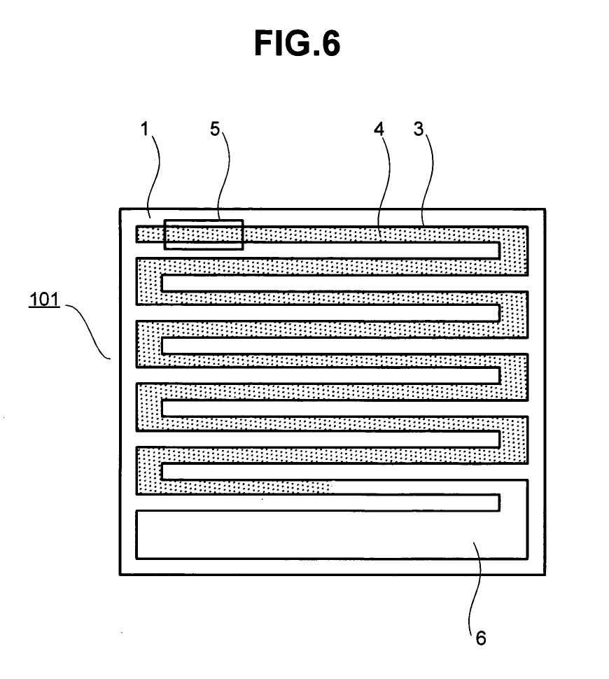

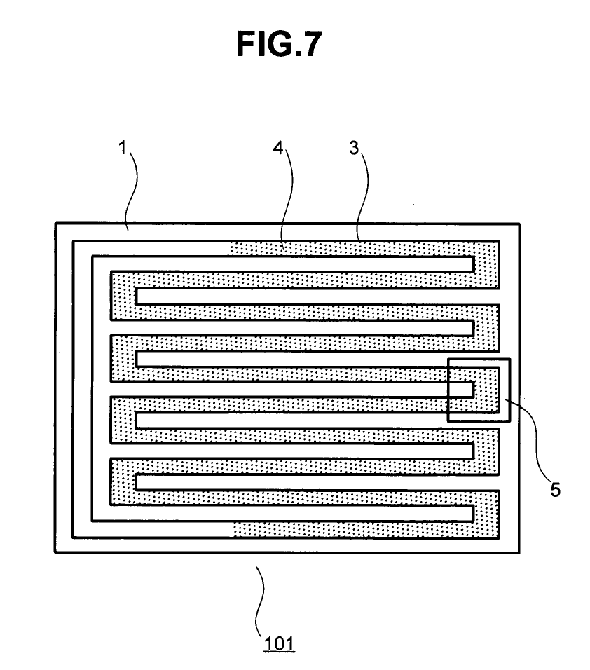

Next, FIGS. 6 and 7 attached herewith show other example about the passage duct 3 formed in the flow passage (or the heat transfer) layer (or the substrate) 15, building up the integrated circuit board 1 according to the present invention. Thus, the passage duct 3 shown in FIG. 6 is one (1) piece, and is one example of forming it in zigzag manner, winding around over the entire surface of the substrate. However, as is shown in the figure, the resistor film 5 is providedat the left-hand side in an upper portion in the figure, and also the buffer 6 is formed at the position opposing to where the resistor film 5 is formed (i.e., the lower side in the figure).

Also, in FIG. 7, the passage duct 3 formed therein is only one (1) piece, as well as, winding around over the entire surface of the substrate in the zigzag manner, however both end portions thereof are connected with each other, thereby being in circular-like in the shape thereof, as a whole. However, in the example of this figure, the resistor film 5 building up the driving means is provided at a central portion on the right-hand side in the figure, while the buffer 6 is formed at the position opposing to where the resistor film 5 is formed (i.e., the left-hand side in the figure).

Thus, in those other examples in relation with the passage duct 3, since the passage duct 3 is only one (1) piece, and also the resistor film 5 is only one (1) set, for building up the driving means thereof, it can be manufactured, easily, therefore it is suitable for providing the integrated circuit board being relatively small in sizes and cheap in the price.

As was fully apparent from the detailed description given in the above, according to the present invention, it is possible to achieve the semiconductor integrated circuit device and also the semiconductor integrated circuit chip for it, enabling the small-size and/or light-weight of the cooling structure thereof, while lowering and suppressing the differences in the thermal distribution, such as, the hot spot generated within the semiconductor chip, representatively, with certainty, accompanying the small-sizing of the chip and/or application of the System On Chip, but without reducing the permissible temperature of the integrated circuit package, in which the semiconductor chip is mounted.

The present invention may be embodied in other specific forms without departing from the spirit or essential feature or characteristics thereof. The present embodiment(s) is/are therefore to be considered in all respects as illustrative and not restrictive, the scope of the invention being indicated by the appended claims rather than by the forgoing description and range of equivalency of the claims are therefore to be embraces therein.

What is claimed is:

1. A semiconductor integrated circuit chip, being made of a plate-like semiconductor chip, comprising:
a circuit forming layer, being formed on one side surface of the plate-like semiconductor chip, in which a plural number of circuits are formed; and
a heat transfer layer, being connected with the plate-like semiconductor chip in one body, on other side surface opposing to that where said circuit forming layer is formed, wherein said heat transfer layer is made of a material similar to that of said semiconductor chip, and comprises, in an inside thereof:
a closed flow passage;
an operating fluid hermetically enclosed within said closed flow passage; and
driving means of said operating fluid the followings.

2. The semiconductor integrated circuit chip, as described in the claim 1, wherein both said plate-like semiconductor chip and said heat transfer layer are made of a material of silicon.

3. The semiconductor integrated circuit chip, as described in the claim 1, wherein said driving means of the operating fluid is made of means for giving vibration to said operating fluid hermetically enclosed within said closed flow passage.

4. The semiconductor integrated circuit chip, as described in the claim 3, wherein said vibration giving means is made up with an resistor layer.

5. The semiconductor integrated circuit chip, as described in the claim 4, wherein said resistor layer is disposed in a region where heat generation density is lower than an averaged heat generation density of said integrated circuit chip as a whole.

6. The semiconductor integrated circuit chip, as described in the claim 1, wherein said operating fluid is water.

7. The semiconductor integrated circuit chip, as described in the claim 1, wherein said plate-like semiconductor chip is of such a chip, wherein logic elements and memory elements are formed separately within the one side surface thereof, on which the circuits are formed.

8. The semiconductor integrated circuit chip, as described in the claim 1, wherein the closed flow passages, being formed in said heat transfer layer, are formed in a plural number thereof, along with one side of said semiconductor chip.

9. The semiconductor integrated circuit chip, as described in the claim 8, wherein each of the closed flow passages formed in the plural number thereof has the means for driving the operating fluid enclosed within an inside thereof, independently.

10. The semiconductor integrated circuit chip, as described in the claim 9, further comprising a plural number of temperature detecting means are provided within said semiconductor chip, wherein said plural number of driving means provided independently are controlled depending upon temperature detection outputs from said temperature detecting means.

11. The semiconductor integrated circuit chip, as described in the claim 8, further comprising other plural number of closed flow passages, being formed along with other side of said semiconductor chip, crossing over the plural number of said closed flow passages formed.

12. The semiconductor integrated circuit chip, as described in the claim 11, wherein each of said closed flow passages formed in the plural number thereof has means for driving the operating fluid enclosed within an inside thereof, independently.

13. The semiconductor integrated circuit chip, as described in the claim 12, further comprising a plural number of temperature detecting means are provided within said semiconductor chip, wherein said plural number of driving means provided independently are controlled depending upon temperature detection outputs from said temperature detecting means.

14. A semiconductor integrated circuit chip, comprising:
a plate-like semiconductor chip;
a circuit forming layer, being formed on one side surface of said plate-like semiconductor chip, on which a plural number of circuits are formed; and
a heat transfer layer, being formed on other side surface opposing to the side surface on which said circuit forming layer is formed, for suppressing a local increase of temperature caused due to heat generation of the circuit within said circuit forming layer of said semiconductor chip, being connected therewith in one body.

15. A semiconductor integrated circuit device, comprising:
a semiconductor integrated circuit chip, in a part of which are formed circuits in a plural number thereof;
a mounting board, in a part of which are formed wiring patterns, for mounting said integrated circuit chip thereon;
a case for receiving said mounting board, on which said integrated circuit board is mounted, in an inside thereof; and
a plural number of terminals, being planted outside from said case or said mounting board, and being electrically connected to the circuits formed on said semiconductor integrated circuit chip, wherein said semiconductor integrated circuit chip is such the semiconductor integrated circuit chip as described in the claim 1.

16. The semiconductor integrated circuit device, as described in the claim 15, further comprising a heat sink, being attached on a part of an outer surface of said case.

17. The semiconductor integrated circuit device, as described in the claim 15, wherein the electric power to be supplied to said driving means, which is formed in said heat transfer layer of said semiconductor integrated circuit chip, is a part of the electric power to be supplied to said semiconductor integrated circuit chip through said terminals of said semiconductor integrated circuit device.

18. A semiconductor integrated circuit device, comprising:
a semiconductor integrated circuit chip, in a part of which are formed circuits in a plural number thereof;
a mounting board, in a part of which are formed wiring patterns, for mounting said integrated circuit chip thereon;
a case for receiving said mounting board, on which said integrated circuit board is mounted, in an inside thereof; and
a plural number of terminals, being planted outside from said case or said mounting board, and being electrically connected to the circuits formed on said semiconductor integrated circuit chip, wherein said semiconductor integrated circuit chip is such the semiconductor integrated circuit chip as described in the claim 14.

19. The semiconductor integrated circuit device, as described in the claim 18, further comprising a heat sink, being attached on a part of an outer surface of said case.

20. The semiconductor integrated circuit device, as described in the claim 18, wherein the electric power to be supplied to said driving means, which is formed in said heat transfer layer of said semiconductor integrated circuit chip, is a part of the electric power to be supplied to said semiconductor integrated circuit chip through said terminals of said semiconductor integrated circuit device.
